(19) United States
(12) Patent Application Publication
(10) Pub. No.: US 2010/0200887 A1
(43) Pub. Date: Aug. 12, 2010

(54) LIGHT EMITTING DEVICE

(75) Inventors: Youji Urano, Ikeda-shi (JP); Kenichiro Tanaka, Neyagawa-shi (JP)

Correspondence Address: EDWARDS ANGELL PALMER & DODGE LLP, P.O. BOX 55874, BOSTON, MA, 02205, US

(73) Assignee: Panasonic Electric Works Co., Ltd., Osaka (JP)

(21) Appl. No.: 12/733,399

(22) PCT Filed: Aug. 28, 2008
(86) PCT No.: PCT/JP2008/065417

§ 371 Date: Feb. 26, 2010

(30) Foreign Application Priority Data
Aug. 28, 2007 (JP) 2007-221864

(51) Int. Cl. H01L 33/50

(52) U.S. Cl. 257/98; 257/E33.061

(57) ABSTRACT

A light emitting device including a thinned color conversion layer which emits a light with a minimized color ununiformity. The light emitting element includes an LED chip, a color conversion layer. The color conversion layer is made of a light-transmissive material containing a phosphor. The phosphor is excited by a light emitted from the LED chip to emit a light of a color having a wavelength longer than that of a luminescent color of the LED chip. The LED chip is provided at its top surface with a frame-shaped electrode which extends along its edge. The color conversion layer is formed on the top surface of the LED chip at an area surrounded by the frame-shaped electrode.

### TECHNICAL FIELD

This invention relates to a light emitting element using LED chip (light emitting diode chip).

### BACKGROUND ART

Many studies have been widely carried out to develop light emitting element which radiates a desired colored light (e.g., white-color light) and light emitting device using the light emitting element so far. (e.g., References 1, 2, and 3) The light emitting element includes an LED chip and a color conversion layer which is made of a light-transmissive material containing phosphor. The phosphor is excited by a light emitted from the LED chip and emits a light of color different from the luminescent color of the LED.

The references 1 and 2 disclose a technique of forming a color conversion layer on one surface of the LED chip by using an ink-jet method. The reference 3 discloses a light emitting device in which an LED chip and a frame surrounding the LED chip therewith are provided on a substrate. In this light emitting device, a portion surrounded by the frame is filled with an encapsulating member made of a light-transmissive material containing a phosphor.

In fabrication of the light emitting elements disclosed in references 1 and 2, the color conversion member is formed directly on the LED chip by using ink-jet method. In this method, the color conversion member can be provided at its desired portion, even when the LED chip is provided at its one surface with an electrode. However, the color conversion layer may be formed with a bumpy surface when thinned, possibly causing color ununiformity.

In fabrication of the light emitting device disclosed in reference 3, thickness of the color conversion layer varies with a height gap between the LED chip and the frame mounted on the substrate. It possibly causes ununiformity in thickness of the color conversion layer.
Reference 1: Japanese unexamined patent publication 2003-46124
Reference 2: Japanese unexamined patent publication 2006-86191
Reference 3: Japanese unexamined patent publication 2005-93601

### DISCLOSURE OF THE INVENTION

The present invention has been accomplished in view of the above problem, and intended to provide a light emitting element with a thinned color conversion layer, which emits a light with a minimized color ununiformity.

The light emitting element comprises an LED chip, a color conversion layer, and a frame-shaped electrode. The color conversion layer is made of a light-transmissive material containing a phosphor. The phosphor is excited by a light emitted from the LED chip to emit a light of a color having a wavelength longer than that of a luminescent color of the LED chip. The frame-shaped electrode is disposed on a top surface of the LED chip and extends along its edge. The color conversion layer is formed on the top surface of the LED chip at an area surrounded by the frame-shaped electrode. In fabrication of the light emitting element of this invention, the color conversion layer can be formed by the process of applying the light-transmissive material in suitable amount which contains a phosphor, to a portion confined by the frame-shaped electrode. According to this method, the color conversion layer can be free from a bumpy surface when thinned, which emits a light with a minimized color ununiformity.

Preferably, a partition is formed integrally with the electrode on the top surface of the LED chip to divide the area surrounded by the electrode into a plurality of sections. The color conversion layer is formed on the top surface of the LED chip at an area surrounded by the electrode and the partition.

### BRIEF DESCRIPTION OF THE DRAWINGS

FIG. 1 shows a schematic sectional view of a light emitting device using a light emitting element of the present invention, in accordance with one embodiment.

FIG. 2 shows a schematic plane view of the light emitting element for utilized in the light emitting device.

FIG. 3 shows a schematic perspective view of the above light emitting element for utilized in the light emitting device.

FIG. 4 shows a schematic plane view of another example of the light emitting element for utilized in the light emitting device.

FIG. 5 shows a schematic sectional view of the example of the light emitting element in FIG. 4 for utilized in the light emitting device.

FIG. 6 shows a schematic perspective view of the example of the light emitting element in FIG. 4 for utilized in the light emitting device.

### BEST MODE FOR CARRYING OUT THE INVENTION

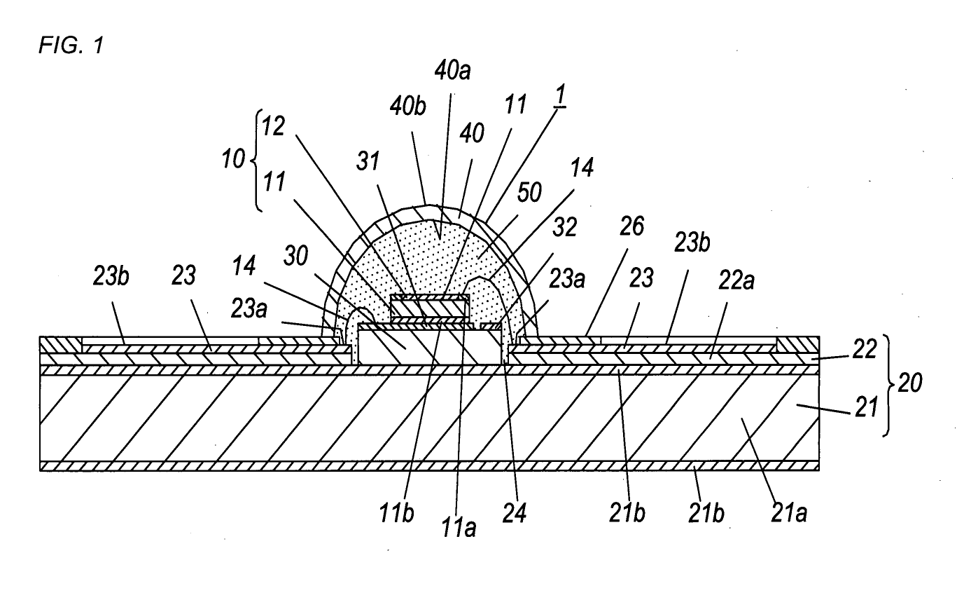

As shown in FIGS. 1, the light emitting device 1 in this embodiment comprises an LED chip 11 emitting a visible light (blue light in this embodiment), a mounting substrate 20 holding the LED chip 11, a dome-shaped optical member 40, an encapsulation resin 50. The optical member 40 is disposed on the same surface of the mounting substrate 20 as that holds LED chip, as well as covering the LED chip 11 therewith. The encapsulation resin 50 is disposed in an area confined between the optical member 40 and the mounting substrate 20 so as to encapsulate the LED chip 11 therewith. The LED chip 11 is provided at its top surface (light output surface) with a color conversion layer 12. The color conversion layer 12 is formed a light-transmissive material and contains a phosphor which is excited by a light emitted from the LED chip 11 to emit a light of a color having a wavelength longer than that of a luminescent color of the LED chip. The LED chip 11 and the color conversion layer 12 are formed to define a light emitting element 10.

In the light emitting device 1 of this embodiment, the LED chip 11 is a GaN-based blue-light LED chip emitting blue-light. The phosphor in the color conversion layer 12 is a yellow phosphor which is excited by a blue light emitted from the LED chip 11 to emit a yellow-light. In this configuration, the blue-light is allowed to pass through the color conversion layer 12 and the encapsulation resin 50 after emitted from the LED chip 11. The yellow-light is allowed to pass through the encapsulation resin 50 after emitted from the yellow phosphor in the color conversion layer 12. In this configuration, the blue-light and the yellow-light are mixed with each other, then guided to a light input surface 40a of the optical member 40, and subsequently radiated as a white-light through a light output surface 40b of the optical member 40.

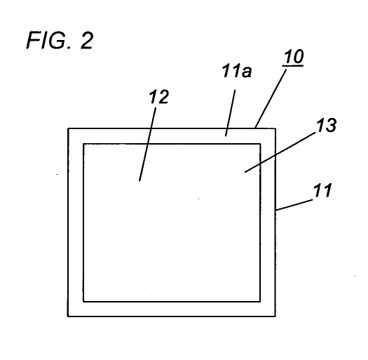

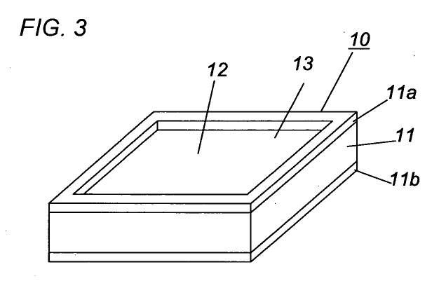

The LED chip 11 is formed at its top surface and its bottom surface with an electrode 11a, and an electrode 11b, respectively, as shown in FIGS. 2 and 3. Each of the electrodes 11a, 11b is formed as a laminate including an upper Au film and a lower Ni film. The LED chip 11 used in this embodiment hardly leaks a blue-light from its lateral face.

The mounting substrate 20 is composed of a rectangular heat conducting plate 21 and a printed substrate 22 which is disposed to a top surface of the heat conducting plate 21 by way of a securing sheet (not shown) such as a polyolefin sheet. The printed substrate 22 is made of a rectangular flexible printed substrate, and formed at its middle position with a rectangular opening 24. A dielectric substrate 30 having a thermal conductivity is disposed on a top surface of the heat conducting plate 21 to pass through the opening 24 of the printed substrate 22. In this configuration, the heat generated from the LED chip 11 is allowed to be dissipated through the dielectric substrate 30 and the heat conducting plate 21, and not introduced to the printed substrate 22.

The heat conducting plate 21 includes a metal plate 21a which is made of Cu and acts as a base plate. The metal plate 21 is provided at its top and bottom surfaces with coating films 21b made of Au film.

The printed substrate 22 includes a dielectric plate 22a. The dielectric plate 22a is made of a polyimide film. The dielectric plate 22a is provided at its top surface with a pair of patterned conductors 23 which supplies electricity to the LED chip 11, and a resist layer 26 made of a white resin which is disposed on the patterned conductor 23. The electrode 11a disposed on the LED chip 11 is electrically connected to one of the patterned conductors 23 through the bonding wire 14. The electrode 11b disposed on the LED chip is connected to the patterned electrode 31 provided on the dielectric substrate 30 and electrically connected to the other of patterned conductors 23 through the bonding wire 14. Each of the patterned conductors 23 is formed into substantially rectangular shape, and has a dimension marginally smaller than half of dimension of the dielectric plate 22a. The dielectric plate 22a may be formed of FR4, FR5, paper phenol, or the like.

The resist layer 26 is formed to expose one portions of the patterned conductor 23 acting as terminal portions 23a nearby the opening 24 of the printed substrate 22. The resist layer 26 is formed to expose other circular portions of the patterned conductor acting as circular electrodes 23b near circumference of, the printed substrate 22. The patterned conductor 23 provided on the printed substrate 22 is made as a laminate including a Cu film, a Ni film, and an Au film which is formed at its top.

The dielectric substrate 30 is made of dielectric AIN exhibiting relatively high thermal conductivity, and formed to have a plane size larger than a chip size of the LED chip 11. The dielectric substrate 30 is acts to relieve stress acting on the LED chip 11 due to a difference of coefficient of linear expansion between the LED chip 11 and the heat conducting plate 21. The dielectric substrate 30 also acts to dissipate heat generated from the LED chip 11 to the heat conducting plate 21 which has a dimension larger than a chip size of the LED chip 11. The dielectric substrate 30 can efficiently dissipate heat generated from the LED chip 11 through the dielectric substrate 30 and the heat conducting plate 21, and can relieve stress acting on the LED chip 11 due to a difference of coefficient of linear expansion between the LED chip 11 and the heat conducting plate 21.

The dielectric substrate 30 is formed of a dielectric AIN exhibiting relatively high thermal conductivity in this embodiment, but may be formed of a composite SiC instead of AIN. The dielectric substrate 30 is provided at its top surface with the patterned electrode 31 which is connected to the other electrode 11b of the LED chip 11 facing the dielectric substrate 30. The dielectric substrate 30 is provided at its top surface with the reflecting film 32. The reflecting film 32 is formed around a periphery of the patterned electrode 31, and configured to reflect thereon the visible light. The reflecting film 26 enables to prevent the visible light emitted from the LED chip 11, from being absorbed into the dielectric substrate 30, so as to achieve a further improved light output. The patterned electrode 31 is formed of an alloy including Au and Sn (e.g., 80Au-20Sn, 70Au-30Sn). The reflecting film 32 is formed of Al, but may be formed of Ag, Ni, Au, or the like instead of Au.

In the light emitting device 1 of this embodiment, the dielectric substrate 30 is arranged to be thick enough to have a top higher than a top of the resist layer 26. With this arrangement, the light is prevented from being absorbed into the printed substrate 22 through an inner wall of the opening 24, after emitted from the LED chip 11 and the yellow phosphor.

The encapsulation resin 50 is made of a silicon resin, but may be made of other one such as an epoxy resin.

The optical member 40 is a dome-shaped molded article made of light-transmissive material (e.g., silicone resin). In this embodiment, the optical member 40 is a molded article made of silicone resin, enabling to minimize differences in refractive index and linear expansion coefficient between the optical member 40 and the encapsulation resin 50. Preferably, the optical member 40 is made of an epoxy resin when the encapsulation resin 50 is an epoxy resin.

The light conversion layer 12 is formed of a phosphor and a light-transmissive material. In this embodiment, a yellow phosphor is used as the phosphor in this embodiment. A silicone resin is used as the light-transmissive material in this embodiment. The light conversion layer 12 may be formed of other light-transmissive material such as acryl resin, instead of a silicone resin.

In the light emitting device 1 in this embodiment, the color conversion layer 12 is formed of a light-transmissive material and a yellow phosphor which is excited by blue-light emitted from the LED chip 11 to emit yellow light. As being disposed on a top surface of the LED chip 11, the color conversion layer 12 enables to enhance heat radiation by dissipating heat of the yellow phosphor contained therein toward the mounting substrate 20 through the LED chip 11. In this light emitting device 1, the optical member 40 is designed to have a spherical light output surface 40b. The light emitting device has a half-sphere lens which is formed of the optical member 40 and the encapsulation resin 50, and is possibly utilized as a point light source.

Next, explanations are given as to the light emitting element 10 which is formed of the LED chip 11 and the color conversion layer 12.

In the light emitting device of this embodiment, a frame-shaped electrode 11a is disposed on the top surface of the LED chip 11 to extend along its edge. The color conversion layer 12 is formed on the top surface of the LED chip 11 inside an area 13 surrounded by the frame-shaped electrode 11a.

In fabrication of the light emitting element 10, the LED chip 11 is provided at its top surface with the frame-shaped electrode 11a and the color conversion layer 12. The light-transmissive material containing the phosphor is applied in suitable amount on the area 13 surrounded by the frame-shaped electrode 11a by means of dispenser or the like, so as to become the color conversion layer 12. This fabrication method enables to provide the light emitting element 10 with a thinned color conversion layer, as well as minimizing a color ununiformity of light by improving flatness of the surface of color conversion layer 12. This fabrication method also enables to define the thickness of the color conversion layer 12 based on thickness of the electrode 11a.

In the light emitting device 10 of this embodiment, the LED chip 11 is provided at its top surface with the frame-shaped electrode 11a. The color conversion layer 12 is formed on the top surface of the LED chip 11 at the area confined by the frame-shaped electrode 11a. The frame-shaped electrode 11a is disposed on a top surface of the LED chip 11 and extends along its edge. In fabrication of the color conversion layer 12 in this arrangement, the light-transmissive material containing the phosphor can be applied in suitable amount at the area surrounded by the frame-shaped electrode. The fabrication process enables to provide the thinned color conversion layer 12 with a further smoothed surface, for giving an almost evenly colored light. Other member may be disposed on the electrode 11a to define the thickness of the color conversion layer 12, when it is difficult to define this thickness only by the electrode 11a. Then, the color conversion layer 12 can be formed at an area defined by the electrode 11a and the other member.

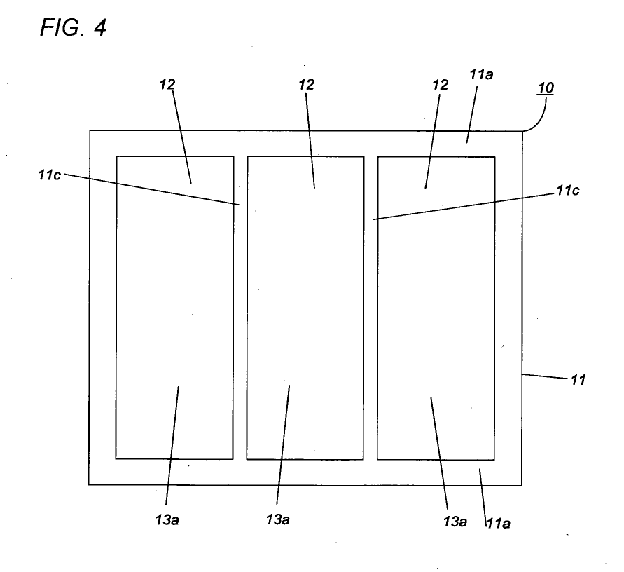

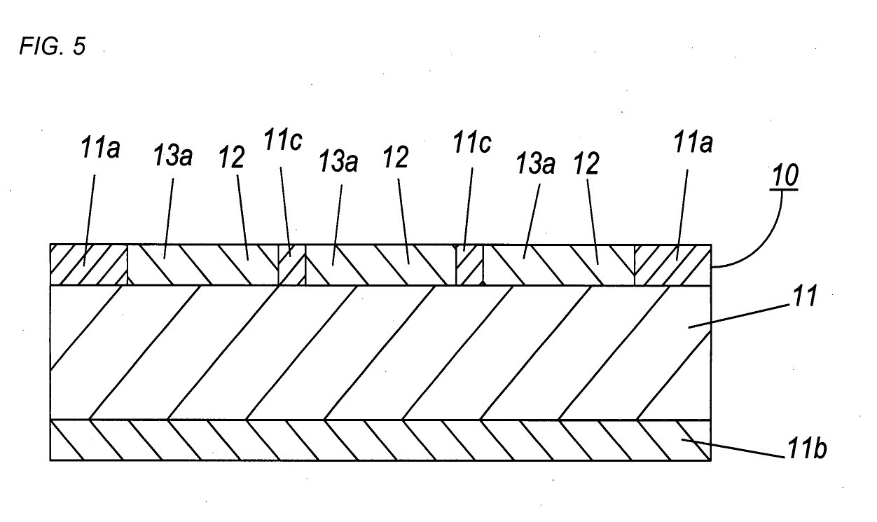

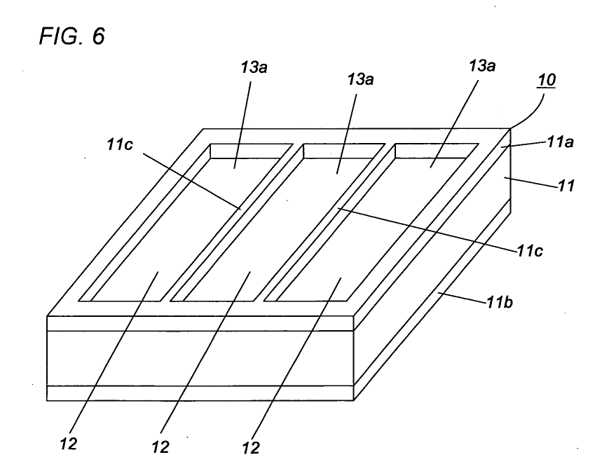

As shown in FIGS. 4 to 6, the LED chip 11 in this embodiment is provided at its top surface with a partition 11c. The partitions are formed integrally with the frame-shaped electrode 11a on the top surface of the LED chip 11 to divide the area surrounded by the frame-shaped electrode 11a into a plurality of (three in this embodiment) sections 13a. The color conversion layer 12 may be formed on the top surface of the LED chip 11 at each section 13a so as to have a further smoothed surface. As shown in FIGS. 4 to 6, the electrode and partition are configured such that the same volumes are given at all the sections 13a confined thereby, enabling to apply the light-transmissive material containing the phosphor at all the partitions 13a in the same amount for easing the fabrication process.

The LED chip 11 and the phosphor in the color conversion layer 12 may be respectively formed of other materials for achieving other luminescent color combinations. For example, the phosphor in the color conversion layer 12 may be a combination of a red phosphor and a green phosphor, instead of the yellow phosphor alone, for giving a white-color light with an improved color rendition. The LED chip 11 may be selected to radiate purple-light to be combined with red-, green-, and blue-phosphors for giving a white-color light. The light emitting device includes only one light emitting element 10, but may include a plurality of light emitting elements 10. A plurality of the light emitting elements 10 may be individually mounted on a plurality of the dielectric substrates 30, or mounted together on one dielectric substrate 30.

1. A light emitting element comprising;
an LED chip;
a color conversion layer made of a light-transmissive material containing a phosphor;
a frame-shaped electrode which is disposed on a top surface of said LED chip and extends along its edge;
said phosphor being excited by a light emitted from said LED chip to emit a light of a color having a wavelength longer than that of a luminescent color of said LED chip,
said color conversion layer being formed on said top surface of said LED chip at an area surrounded by said frame-shaped electrode.

2. The light emitting element as set forth in claim 1, further comprising
a partition being formed integrally with said electrode on said top surface of said LED chip to divide said area surrounded by said electrode into a plurality of sections,
said color conversion layer being formed on said top surface of said LED chip at an area surrounded by said electrode and said partition.
